(19) United States
(12) Patent Application Publication
(10) Pub. No.: US 2018/0040607 A1
(43) Pub. Date: Feb. 8, 2018

(54) LTPS Display Panel And Manufacturing Method For The Same

(71) Applicant: Wuhan China Star Optoelectronics Technology Co., Ltd., Wuhan, Hubei (CN)

(72) Inventors: Bin XIONG, Shenzhen, Guangdong (CN); Lulu XIE, Shenzhen, Guangdong (CN); Yun HAN, Shenzhen, Guangdong (CN); Zhenzhou XING, Shenzhen, Guangdong (CN)

(73) Assignee: Wuhan China Star Optoelectronics Technology Co., Ltd., Wuhan, Hubei (CN)

(21) Appl. No.: 14/914,243

(22) PCT Filed: Jan. 29, 2016
(86) PCT No.: PCT/CN2016/072819

§ 371 Date: Feb. 24, 2016

(30) Foreign Application Priority Data
Dec. 31, 2015 (CN) 201511029054.1

(51) Int. Cl. H01L 27/02; H01L 27/12

(52) U.S. Cl. CPC H01L 27/0288; H01L 27/0292; H01L 27/1222; H01L 27/1259; G02F 1/133514

(57) ABSTRACT

A LTPS display panel and manufacturing method for the same. The LTPS display panel includes a color filer, a black matrix located on the color filter and a TFT substrate located at a side of the black matrix and disposed oppositely to the color filter, wherein, a conductive ring is disposed outside the black matrix and disposed on the color filter, a separation groove is disposed between the conductive ring and the black matrix, one or multiple ground pin is provided on the TFT substrate, the conductive ring on the color filter and the ground pin on the TFT substrate are electrically connected in order to form an ESD path. The electrostatic charges at the edge of the panel can be released to the earth to prevent ESD poor display cause by crack notch when cutting the panel so as to increase the ESD reliability of the panel.

### BACKGROUND OF THE INVENTION

### 1. Field of the Invention

The present invention relates to an LTPS display technology field, and more particularly to an LTPS display panel and a manufacturing method for the same.

### 2. Description of Related Art

Along with the improvement of the LTPS (Low Temperature Poly Silicon) equipment and the process art, more and more panel manufacturers gradually invest a lot of energy and cost at the LTPS technology field. The LPTS manufacturing process can make the display panel to have higher pixel per inch (PPI) and narrower frame. The above is benefited from a greater electron mobility of the LTPS.

In a terminal display market, especially a smart phone market, each company is looking for product differentiation and product innovation to disseminate the feature point of a new cell phone. Currently, a narrow frame or even a no-frame design is always a feature point for disseminating by a terminal brand. The demand of the terminal customer makes the panel manufacturers to continuously search the limit of the frame. However, because the characteristic of the glass and the structure of the panel such that a width of the frame has reached a physical limit.

In the conventional art, with reference to FIG. 1, the periphery of the panel is surrounded with dense circuits such as GOA (Gate On Array) unit circuit, ESD (Electric Static Discharge) protection circuit and so on. The circuits are located at the outermost of the panel. With reference to FIG. 2 and FIG. 3, the LTPS display panel usually includes a color filter (CF) 10, a black matrix 20 located at a middle portion of the color filter and a TFT substrate 30 disposed oppositely to the black matrix (BM) 20. Because the frame is more and more narrow such that when cutting the panel, fine cracks and notches are easily to generate as shown in FIG. 2. The cracks and notches make the periphery of the panel to generate a sharp terminal so that ESD (Electric Static Discharge) charges are easily to accumulate. Because the requirement of a narrow frame, a cutting edge of the panel is very close to an edge of the BM so that the fine cracks and notches generated when cutting the panel are easily to be connected with the black matrix. Accordingly, the accumulated ESD charges are moved to the black matrix BM such that the black matrix BM carries the electrostatic charges. When the black matrix BM carries the electrostatic charges, an original normal horizontal electric field will be interfered so that a poor display of the panel is generated.

### SUMMARY OF THE INVENTION

In order to overcome the deficiency of the conventional art, the purpose of the present disclosure is to provide a LTPS display panel and a manufacturing method for the same.

In order to achieve the above purpose, a technology solution provided by the embodiment of the present disclosure is:

A low temperature poly-silicon (LTPS) display panel, comprising a color filer, a black matrix located on the color filter and a TFT substrate located at a side of the black matrix and disposed oppositely to the color filter, wherein, a conductive ring is disposed outside the black matrix and disposed on the color filter, a separation groove is disposed between the conductive ring and the black matrix, one or multiple ground pin is provided on the TFT substrate, the conductive ring on the color filter and the ground pin on the TFT substrate are electrically connected in order to form an electrostatic discharge (ESD) path.

As a further improvement of the present disclosure, the conductive ring on the color filter and the ground pin on the TFT substrate are electrically connected through a conductive silver paste.

As a further improvement of the present disclosure, the conductive silver paste is disposed at corners of the conductive ring, and the ground pin on the TFT substrate is disposed corresponding to the corners of the conductive ring.

As a further improvement of the present disclosure, a material of the conductive ring and a material of the black matrix are the same.

As a further improvement of the present disclosure, a width of the separation groove is 1˜100 μm.

As a further improvement of the present disclosure, a width of the conductive ring is 100˜1000 μm.

Correspondingly, a manufacturing method for an LTPS display panel, the manufacturing method includes:

providing a color filter, and forming a black matrix and a conductive ring located outside the black matrix on a side of the color filter;

providing a TFT substrate, and disposing one or multiple ground pin on the TFT substrate; and

electrically connecting the conductive ring on the color filter with the ground pin on the TFT substrate in order to form an electrostatic discharge (ESD) path.

As a further improvement of the present disclosure, the ground pin on the TFT substrate is disposed corresponding to corners of the conductive ring.

As a further improvement of the present disclosure, the step of electrically connecting the conductive ring on the color filter with the ground pin on the TFT substrate is:

providing a conductive silver paste between the conductive ring on the color filter and the ground pin on the TFT in order to electrically connect the conductive ring and the ground pin.

In the present invention, through disposing a black matrix and a conductive ring, and forming a separation groove between the black matrix and the conductive ring, the conductive ring is electrically connected with the ground pin on the TFT substrate in order to forms an ESD path. When the crack notch of the panel has ESD charges, the electrostatic charges can be released to the earth through the ESD path to prevent ESD poor display cause by crack notch when cutting the panel so as to increase the ESD reliability of the panel.

### BRIEF DESCRIPTION OF THE DRAWINGS

FIG. 1 is a schematic block diagram of a LTPS display panel in the conventional art;

FIG. 2 is a schematic plane structure diagram of a LTPS display panel in the conventional art;

FIG. 3 is a schematic side structure diagram of a LTPS display panel in the conventional art;

FIG. 4 is a schematic plane structure diagram of a LTPS display panel in an embodiment of the present invention;

FIG. 5 is a schematic side structure diagram of a LTPS display panel in an embodiment of the present invention;

FIG. 6 is a schematic plane structure diagram when a LTPS display panel is discharged in an embodiment of the present invention; and

FIG. 7 is a schematic side structure diagram when a LTPS display panel is discharged in an embodiment of the present invention.

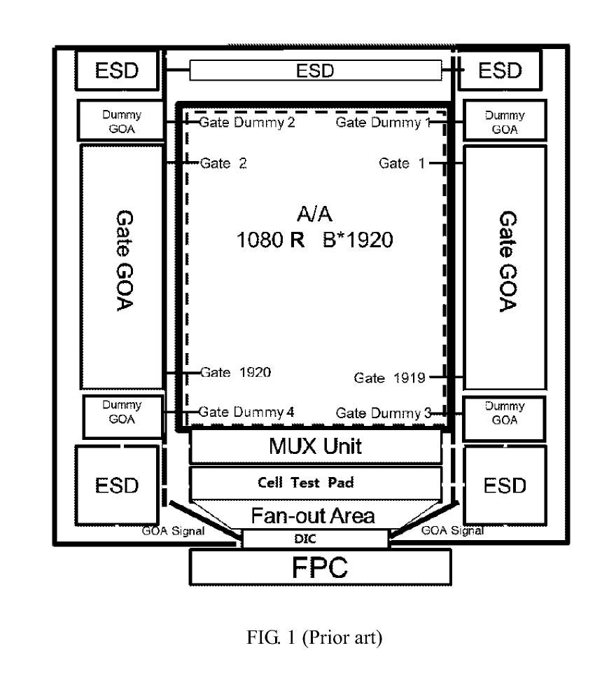

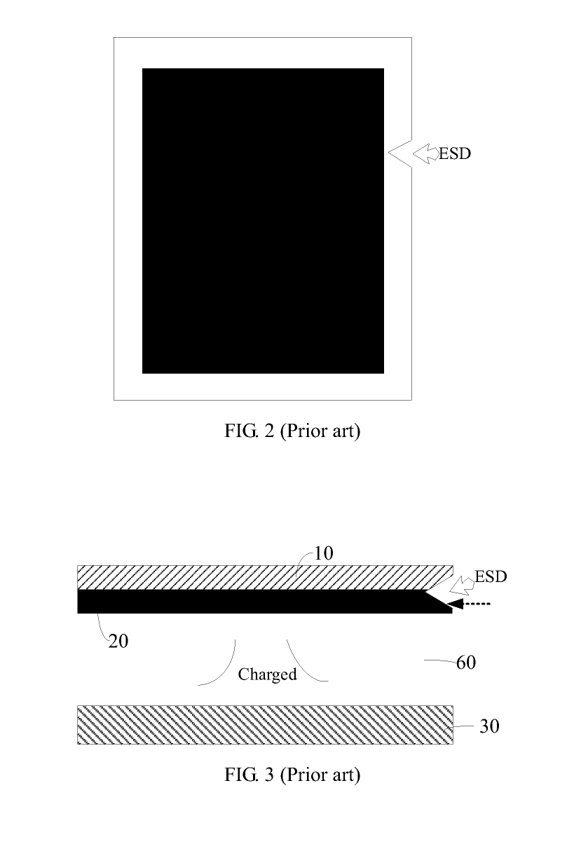

### DETAILED DESCRIPTION OF THE PREFERRED EMBODIMENT

The following content combines with the figures and the embodiment for describing the present invention in detail. It is obvious that the following embodiments are only some embodiments of the present invention. For the person of ordinary skill in the art without creative effort, the other embodiments obtained thereby are still covered by the present invention.

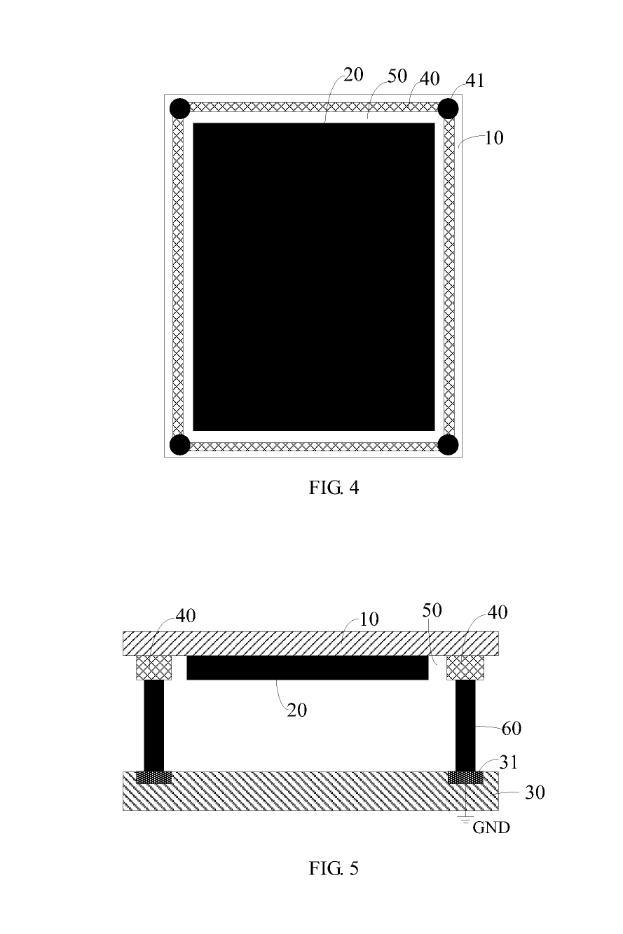

With reference to FIG. 4 and FIG. 5, which show a LTPS display panel of an embodiment of the present invention. The LTPS display panel includes a color filter (CF) 10, a black matrix (BM) 20 located on the color filter 10 and a thin-film transistor (TFT) substrate 30 located at a side of the black matrix 20 and disposed oppositely to the color filter. Between the color filter and the TFT substrate, a liquid crystal layer (not shown in the figure) is provided.

Wherein, a conductive ring 40 is disposed outside the black matrix 20 and on the color filter. A separation groove 50 is disposed between the conductive ring 40 and the black matrix 20. On the TFT substrate 30, one or multiple ground pin 31 is provided. The conductive ring 40 on the color filter and the ground pin 31 on the TFT substrate are electrically connected such that the conductive ring 40 forms a ground ring (GND loop) through the ground pin, and finally forms an ESD discharge path.

In the present embodiment, the conductive ring 40 on the color filter and the ground pin 31 on the TFT substrate are electrically connected through a conductive silver paste 60. As a LTPS display panel shown in FIG. 4, the conductive ring 40 is disposed as a rectangle. Each corner 41 of the conductive ring 40 is provided with the conductive silver paste 60. Through the conductive silver paste 60 to electrically connect the conductive ring at the corners 41 with the ground pin 31 on the TFT substrate, and through the conductive silver paste 60 to connect the conductive ring 40 to an earth ground together.

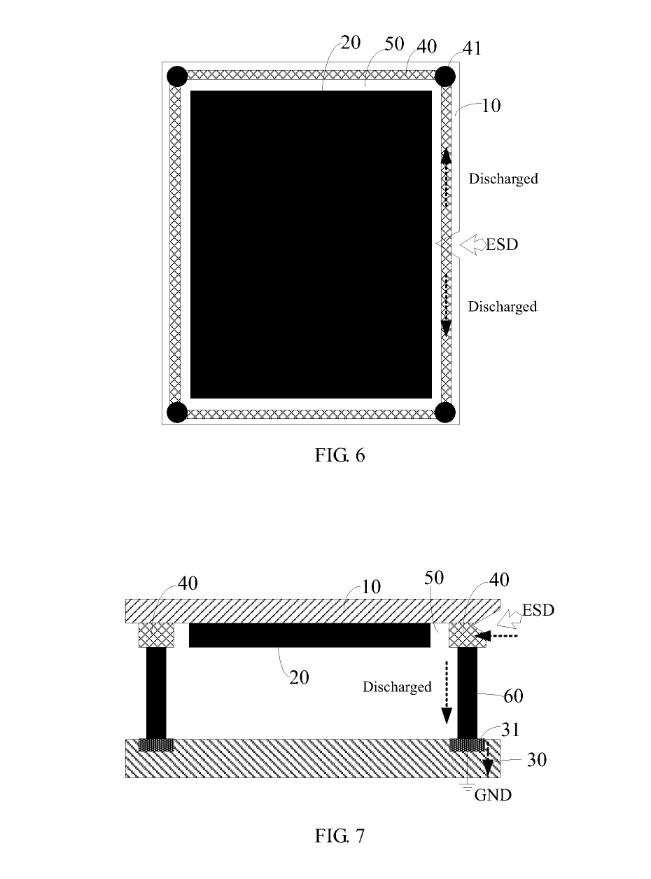

As shown in FIG. 6 and FIG. 7, when electrostatic discharge charges are existed at a crack notch, the electrostatic discharge charges can flow to the ground pin on the TFT substrate through the conductive silver paste at four corners. Then, the electrostatic discharge charges are released to the earth ground in order to avoid the problem of cannot release electrostatic discharge charges and a poor display because of the crack notch generated by cutting the panel.

Furthermore, the separation groove 50 is located between the conductive ring 40 and the black matrix 20 and the separation groove 50 can further prevent the electrostatic discharge charges caused by the crack notch generated by cutting the panel from moving to the black matrix of the color filter such that a surface of the black matrix will not form an electric field. Accordingly, the present disclosure will not affect an originally parallel electric field between the TFT substrate and the color filter in order to avoid that tilting angle of liquid crystal molecules is inconsistent with the actual design so as to affect a display finally.

In the present embodiment, a material of the conductive ring 40 and a material of the black matrix 20 are the same. The conductive ring 40 is formed by original black matrix BM having a low resistance. A width of the separation groove 50 is 1˜100 μm. A width of the conductive ring 40 is 100˜1000 μm. Preferably, in an embodiment of the present invention, the width of the separation groove 50 is about 15 μm, and the width of the conductive ring 40 is about 300 μm.

It can be understood that the present embodiment adopts a rectangular conductive ring as an example, and the conductive silver paste is disposed at corners of the rectangular conductive ring. In another embodiment, the conductive ring can be another shape having a closed ring shape. The conductive silver ring can be disposed at all or a portion of corners of the conductive ring, or not to be disposed at the corners of the conductive ring. Here, not giving examples for describing one by one.

Correspondingly, a manufacturing method for the LTPS display panel in above embodiments includes:

providing a color filter, and forming a black matrix and a conductive ring located outside the black matrix on a side of the color filter;

providing a TFT substrate, and disposing one or multiple ground pin on the TFT substrate; and

electrically connecting the conductive ring on the color filter with the ground pin on the TFT substrate in order to form an electrostatic discharge (ESD) path.

Wherein, the step of electrically connecting the conductive ring on the color filter with the ground pin on the TFT substrate is:

providing a conductive silver paste between the conductive ring on the color filter and the ground pin on the TFT in order to electrically connect the conductive ring and the ground pin.

From above technology solutions, in the present invention, through disposing a black matrix and a conductive ring, and forming a separation groove between the black matrix and the conductive ring, the conductive ring is electrically connected with the ground pin on the TFT substrate in order to forms an ESD path. When the crack notch of the panel has ESD charges, the electrostatic charges can be released to the earth through the ESD path to prevent ESD poor display cause by crack notch when cutting the panel so as to increase the ESD reliability of the panel.

For the person skilled in the art, obviously, the present invention is not limited to the detail of the above exemplary embodiment. Besides, without deviating the spirit and the basic feature of the present invention, other specific forms can also achieve the present invention. Therefore, no matter from what point of view, the embodiments should be deemed to be exemplary, not limited. The range of the present invention is limited by the claims not by the above description. Accordingly, the embodiments are used to include all variation in the range of the claims and the equivalent requirements of the claims. It should not regard any reference signs in the claims as a limitation to the claims.

Besides, it can be understood that, although the present disclosure is describe according to the embodiments, each embodiment does not include only on dependent technology solution. The description of the present disclosure is only for clarity. The person skilled in the art should regard the present disclosure as an entirety. Technology solutions in the embodiments can be adequately combined to form other embodiments that can be understood by the person skilled in the art.

What is claimed is:

1. A low temperature poly-silicon (LTPS) display panel, comprising a color filer, a black matrix located on the color filter and a TFT substrate located at a side of the black matrix and disposed oppositely to the color filter, wherein, a conductive ring is disposed outside the black matrix and disposed on the color filter, a separation groove is disposed between the conductive ring and the black matrix, one or multiple ground pin is provided on the TFT substrate, the conductive ring on the color filter and the ground pin on the TFT substrate are electrically connected in order to form an electrostatic discharge (ESD) path.

2. The LTPS display panel according to claim 1, wherein, the conductive ring on the color filter and the ground pin on the TFT substrate are electrically connected through a conductive silver paste.

3. The LTPS display panel according to claim 2, wherein, the conductive silver paste is disposed at corners of the conductive ring, and the ground pin on the TFT substrate is disposed corresponding to the corners of the conductive ring.

4. The LTPS display panel according to claim 1, wherein, a material of the conductive ring and a material of the black matrix are the same.

5. The LTPS display panel according to claim 1, wherein, a width of the separation groove is 1˜100 μm.

6. The LTPS display panel according to claim 1, wherein, a width of the conductive ring is 100˜1000 μm.

7. A manufacturing method for a LTPS display panel, wherein, the manufacturing process comprises:
providing a color filter, and forming a black matrix and a conductive ring located outside the black matrix on a side of the color filter;
providing a TFT substrate, and disposing one or multiple ground pin on the TFT substrate; and
electrically connecting the conductive ring on the color filter with the ground pin on the TFT substrate in order to form an electrostatic discharge (ESD) path.

8. The manufacturing method according to claim 7, wherein, the ground pin on the TFT substrate is disposed corresponding to corners of the conductive ring.

9. The manufacturing method according to claim 7, wherein, the step of electrically connecting the conductive ring on the color filter with the ground pin on the TFT substrate is:
providing a conductive silver paste between the conductive ring on the color filter and the ground pin on the TFT in order to electrically connect the conductive ring and the ground pin.

10. The manufacturing method according to claim 8, wherein, the step of electrically connecting the conductive ring on the color filter with the ground pin on the TFT substrate is:
providing a conductive silver paste between the conductive ring on the color filter and the ground pin on the TFT in order to electrically connect the conductive ring and the ground pin.
